(19) United States
(12) Patent Application Publication
(10) Pub. No.: US 2016/0007445 A1
(43) Pub. Date: Jan. 7, 2016

(54) HIGH-FREQUENCY SIGNAL PROCESSING METHOD

(71) Applicant: KUANG YING COMPUTER EQUIPMENT CO., LTD., New Taipei City (TW)

(72) Inventors: Hsuan-Ho Chung, New Taipei City (TW); Yu-Hung Lin, New Taipei City (TW)

(21) Appl. No.: 14/324,087

(22) Filed: Jul. 4, 2014

(51) Int. Cl. H05K 1/02

(52) U.S. Cl. CPC H05K 1/0216

(57) ABSTRACT

The high-frequency signal processing method provides at least two isolation terminals between adjacent signal transmission conductor sets. For two adjacent signal transmission conductor sets of a substrate, at least two vias through the substrate are embedded with conductive pillars, respectively. Each conductive pillar penetrates the dielectric layers of the substrate from a top side to a bottom side of the substrate. Each via with the embedded conductive pillar functions as an isolation terminal. The signal transmission conductor sets are as such segregated by the isolation terminals and the isolation terminals provides two layers of shielding. With the present invention, there is no requirement of having a casing and the miniaturization of form factors of the electronic appliances is not compromised. The dual isolation terminals significantly suppress the strength and influence of interference produced by a signal transmission conductor.

### BACKGROUND OF INVENTION

(a) Technical Field of the Invention

The present invention is generally related to high-frequency signal processing methods, and more particular to a method providing segmented suppression and successive isolation to the interference produced by signal transmission conductor.

(b) Description of the Prior Art

As electronic appliances are getting more sophisticated, they are also more susceptible to interferences arising from such as electromagnetic waves.

The noises in signal transmission due to various interferences often cause the malfunction of the electronic appliances.

A signal whose frequency is above 2.4 GHz is referred to as a high-frequency signal. High frequency signals cannot be picked up by human hearing but noises are also difficult to filter or remove. Usually a casing and some form of shielding on the casing are employed to isolate the interference, or a ground terminal is added besides the signal terminals so as to reduce high-frequency signal noise.

As shown in FIG. 1, for a 3-layered substrate, an existing isolation structure has a single ground terminal 5 between left and right signal terminals 4 for isolation. For a multi-layered (more than three layers) substrate as shown in FIG. 2, an existing isolation structure also has a single ground terminal 5 between top and bottom signal terminals 4 for isolation.

These existing isolation structures have the following disadvantages.

First of all, the requirement of having a casing limits the further miniaturization of the form factors of the electronic appliances.

Secondly, a single ground terminal 5 has limited isolation effect and noises still require further reduction.

Thirdly, for a multi-layered substrate, the isolation effect of a single ground terminal is even weaker.

### SUMMARY OF THE INVENTION

In order to achieve enhanced interference isolation, the present invention teaches a novel design where shielding is directly applied to the signal source inside an electronic appliance.

A major objective of the present invention is to provide at least two isolation terminals between adjacent signal transmission conductor sets. No matter how the signal transmission conductor sets are arranged, there are always two isolation terminals in between the signal transmission conductor sets.

To achieve the objective, between adjacent signal transmission conductor sets of a substrate, at least two vias through the substrate are embedded with conductive pillars, respectively. Each conductive pillar penetrates the dielectric layers of the substrate from a top side to a bottom side of the substrate. Each via with the embedded conductive pillar functions as an isolation terminal perpendicular to the signal transmission conductor sets. The signal transmission conductor sets are as such segregated by the isolation terminals and the isolation terminals provides two layers of shielding.

With the present invention, there is no requirement of having a casing and the miniaturization of form factors of the electronic appliances is not compromised. The dual isolation terminals significantly suppress the strength and influence of interference produced by a signal transmission conductor. For a multi-layered (more than three layers) substrate, the present invention can include an additional isolation layer between adjacent isolation terminals so as to further enhance the isolation effect.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become apparent to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic diagram showing an existing isolation structure.

FIG. 2 is a schematic diagram showing another existing isolation structure.

FIG. 3 is a perspective schematic diagram showing a substrate where a first embodiment of the present invention is implemented.

FIG. 4 is another perspective schematic diagram showing the substrate of FIG. 3.

FIG. 5 is a sectional schematic diagram showing the substrate along the A-A segment of FIG. 4.

FIGS. 6 to 7 are schematic diagrams showing application scenarios of the first embodiment of the present invention.

FIGS. 8 to 10 are schematic diagrams showing application scenarios of a second embodiment of the present invention.

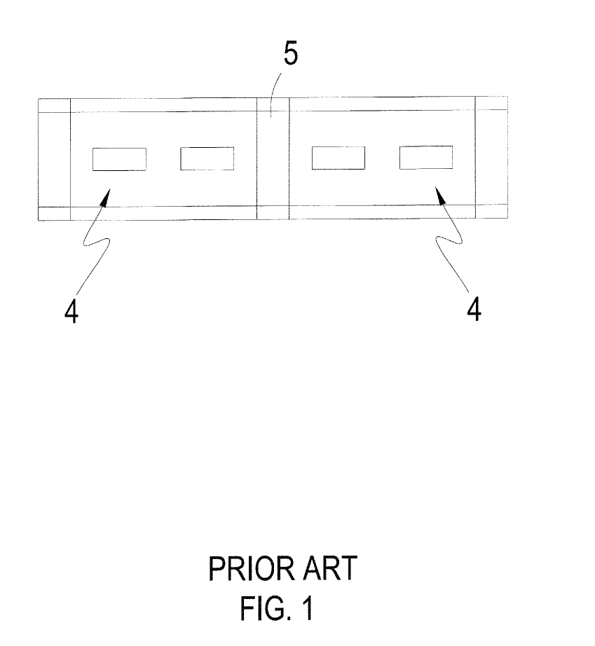

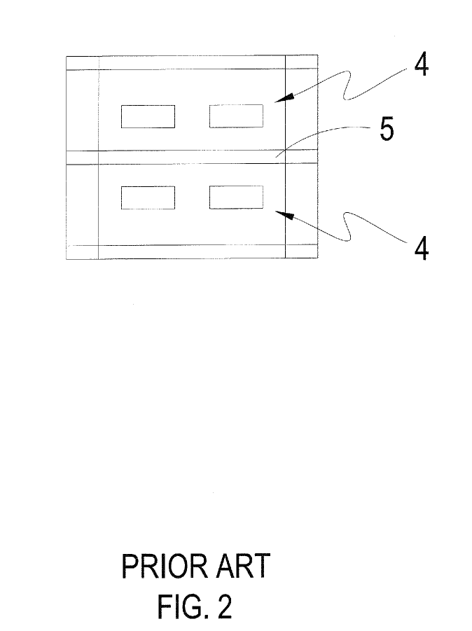

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

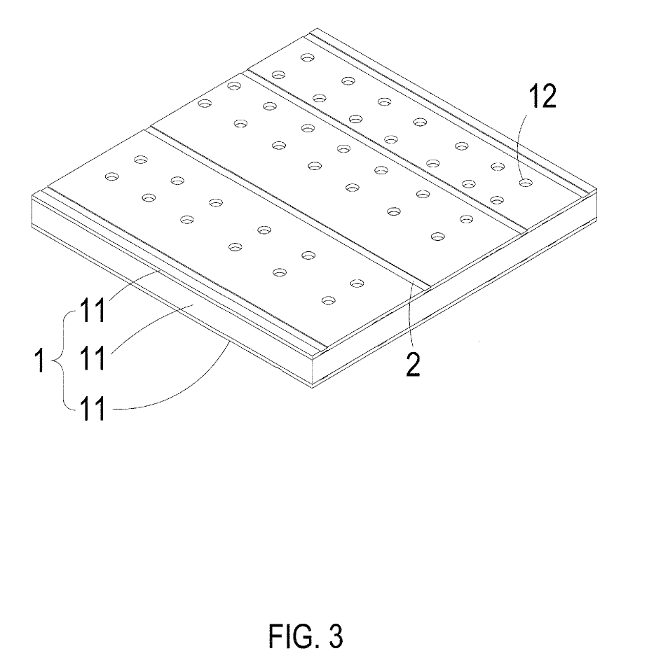

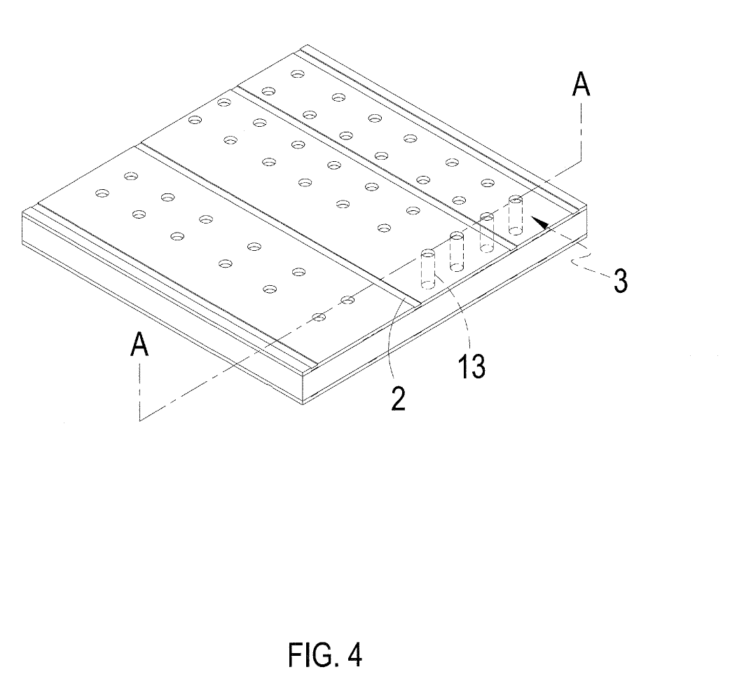

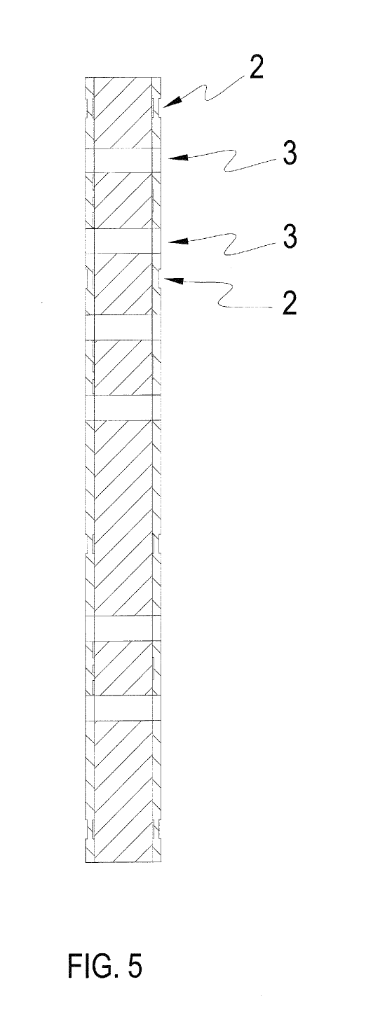

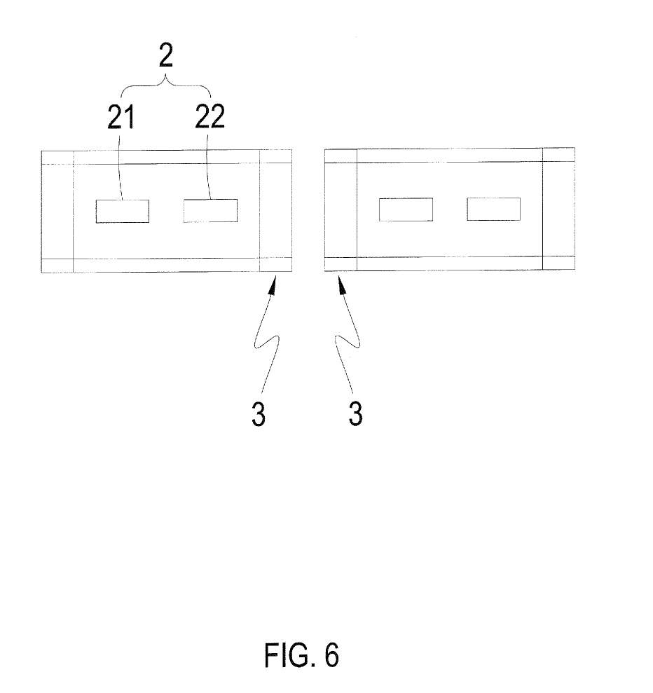

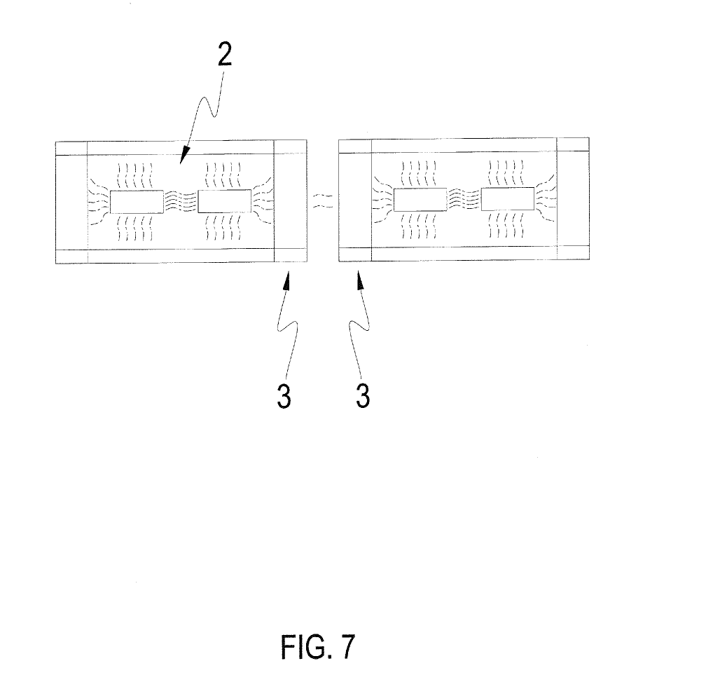

FIGS. 3 and 4 are perspective diagrams showing a substrate where a first embodiment of the present invention is implemented. FIG. 5 is a sectional schematic diagram showing the substrate along the A-A segment of FIG. 4. FIGS. 6 and 7 are schematic diagrams showing application scenarios of the first embodiment of the present invention. As shown in FIGS. 3 to 7, the first embodiment of the present invention is applied to a substrate 1 which contains three dielectric layers 11 stacked together, a number of signal transmission conductor sets 2, and a number of vias 12 penetrating the dielectric layers 11 from a top side to a bottom side of the substrate 1 between adjacent signal transmission conductor sets 2. As shown in FIG. 6, each signal transmission conductor set 2 contains a first signal transmission conductor 21 and a second signal transmission conductor 22. Between adjacent signal transmission conductor sets 2, at least two vias 12 are embedded with conductive pillars 13, respectively. Each conductive pillar 13 penetrates the dielectric layers 11 from the top side to the bottom side of the substrate 1. Each via 12 with the embedded conductive pillar 13 functions as an isolation terminal 3 perpendicular to the signal transmission conductor sets 2. In other words, each pair of signal transmission conductor sets 2 has at least two isolation terminals 3 in between so as to prevent the pair of signal transmission conductor sets 2 to interfere each other. Each isolation terminal 3 can be a positive transmission terminal or a ground transmission terminal. For each signal transmission conductor set 2, it is surrounded by isolation terminals. Additionally, for the two isolation terminals 3 between a first signal transmission conductor set 2 and a second signal transmission conductor set 2, the one that is nearest to the first signal transmission conductor set 2 and farther from the second signal transmission conductor set 2 plays two roles. The isolation terminal 3 provides a first layer of shielding to the nearest first signal transmission conductor set 2, and it also provides a second layer of shielding to the farther second signal transmission conductor set 2. The first layer of shielding blocks most of the high-frequency interference whereas the second layer of shielding blocks the remaining interference. For a signal transmission conductor set 2 that is adjacent to an edge of the substrate 1 and has only one isolation terminal 3 to a side, when two such signal transmission conductor sets 2 of two separate substrates 1 are close to each other, their isolation terminals 3 again plays two roles. The isolation terminal 3 provides a first layer of shielding to the signal transmission conductor set 2 of the same substrate 1, and it also provides a second layer of shielding to the signal transmission conductor set 2 of the other substrate 1. With this design, the present invention therefore achieves segregated suppression and successive isolation of interference, and the high-frequency noise problem is as such effectively resolved.

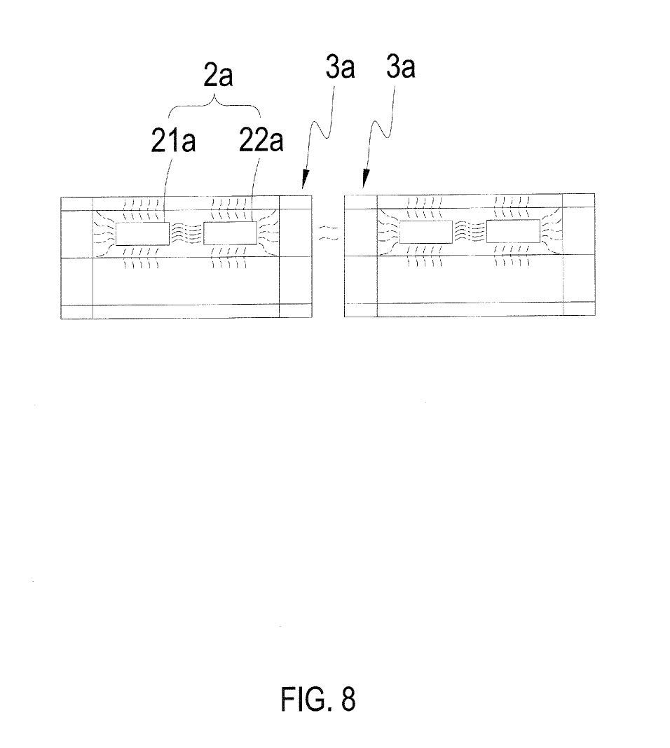

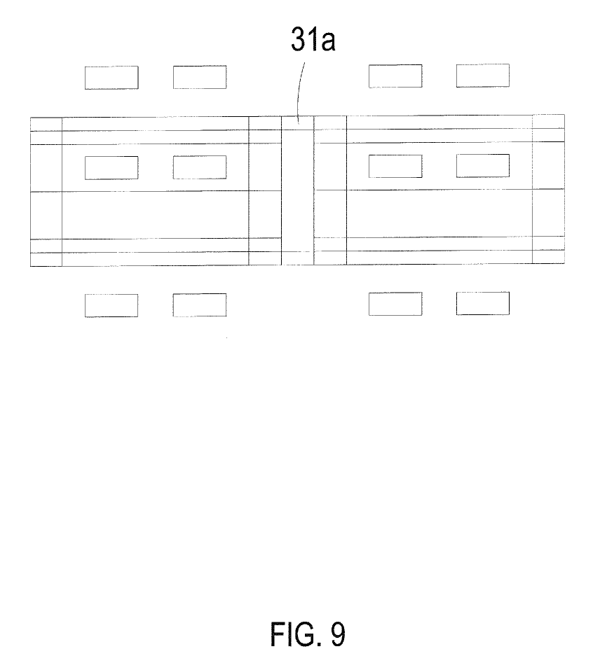

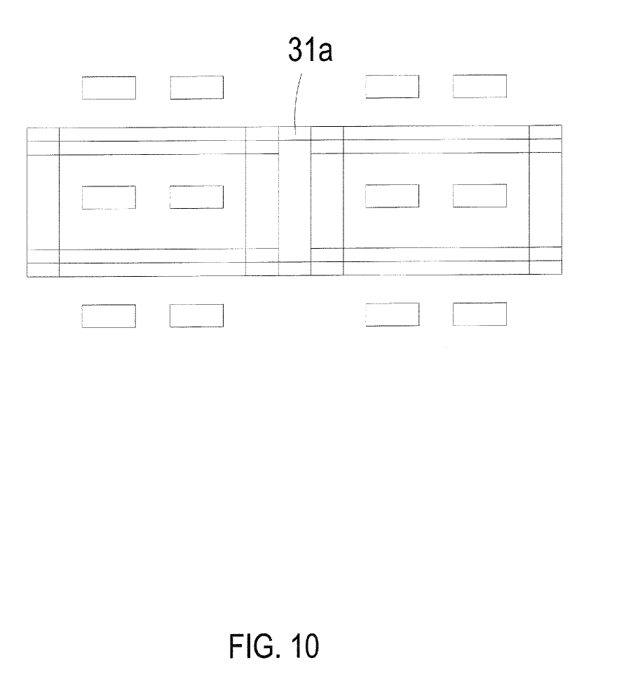

FIGS. 8 to 10 are schematic diagrams showing application scenarios of a second embodiment of the present invention. In this embodiment, the substrate contains four dielectric layers. In addition to the isolation terminals 3a between signal transmission conductor sets 2a as described in the previous embodiment, an additional isolation layer 31a are configured between two adjacent isolation terminals 3a so as to further enhance the isolation effect. More specifically, each signal transmission conductor set 2a contains a first signal transmission conductor 21a and a second signal transmission conductor 22a. When a first signal transmission conductor set 2a has a second signal transmission conductor set 2a nearby, the interference produced by the first signal transmission conductor set 2a is first blocked by the nearest isolation terminal 3a for the most part, and then the remaining interference which should cause little or no impact, is further blocked by the isolation terminal 3 nearest to the second signal transmission conductor set 2a. If there is an isolation layer 31 configured as described, the interference should be reduced to the minimum. The present invention is capable of suppressing interference such as the Electromagnetic Interference (EMI) or the Radio Frequency Interference (RFI).

In addition, as described above, the signal transmission conductor sets can be arranged in various ways such as in parallel, in an array, in a vertical stack in the substrate, as long as there are at least two isolation terminals between adjacent signal transmission conductor sets.

The advantages of the present invention therefore are as follows.

First of all, there is no requirement of having a casing and the miniaturization of form factors of the electronic appliances is not compromised.

Secondly, dual isolation terminals 3 significantly suppress the strength and influence of interference produced by a signal transmission conductor.

Thirdly, for a multi-layered (more than three layers) substrate, the inclusion of an additional isolation layer 31a further enhances the isolation effect.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A high-frequency signal processing method for isolating interference between signal transmission conductor sets, comprising the step of between two adjacent signal transmission conductor sets of a substrate, providing at least two isolation terminals perpendicularly through the substrate.

2. The high-frequency signal processing method according to claim 1, further comprising the step of:
providing an isolation layer between at least a pair of adjacent isolation terminals.

3. The high-frequency signal processing method according to claim 1, wherein the substrate comprises at least three dielectric layers stacked together.

4. The high-frequency signal processing method according to claim 3, wherein the step of providing isolation terminals comprises the step of
providing a plurality of vias between two adjacent signal transmission conductor sets from a top side to a bottom side of the substrate.

5. The high-frequency signal processing method according to claim 4, wherein the step of providing isolation terminals further comprises the step of:
providing a conductive pillar in each of at least two vias between two adjacent signal transmission conductor sets from the top side to the bottom side of the substrate.

6. The high-frequency signal processing method according to claim 1, wherein the interference is one of Electromagnetic Interference (EMI) and Radio Frequency Interference (RFI).

7. A high-frequency signal processing method according to claim 1, wherein the isolation terminal is one of a positive transmission terminal and a ground transmission terminal.

8. A high-frequency signal processing method according to claim 1, wherein the signal transmission conductor set comprises a first signal transmission conductor and a second signal transmission conductor.

9. The high-frequency signal processing method according to claim 1, wherein the signal transmission conductor sets are arranged in parallel, in an array, or in a vertical stack in the substrate.

10. The high-frequency signal processing method according to claim 1, wherein at least an isolation terminal is at a side of each signal transmission conductor set.
